(19) United States
(12) Patent Application Publication
(10) Pub. No.: US 2026/0348704 A1
(43) Pub. Date: Nov. 5, 2026

(54) Stun current generator for small-calibre electric bullets

(71) Applicants: Yuriy Aleksandrovich GABLIYA, g. Moscow (RU); Yuriy Olegovich LADYAGIN, g. Moscow (RU)

(72) Inventor: Yuriy Olegovich LADYAGIN, g. Moscow (RU)

(21) Appl. No.: 19/488,718

(22) PCT Filed: Apr. 19, 2024
(86) PCT No.: PCT/RU2024/000138

§ 371 Date: Nov. 28, 2025

(30) Foreign Application Priority Data
Jun. 1, 2023 (RU) 2023114471

(51) Int. Cl. F41H 13/00; H02M 1/00; H02M 3/00; H02M 3/335; H03K 3/57

(52) U.S. Cl. CPC F41H 13/0031; H02M 1/007; H02M 3/003; H02M 3/33507; H03K 3/57

(57) ABSTRACT

A stun current generator for small-calibre electric bullets contains an electrical power source, an activation switch, a voltage converter, a voltage multiplier, an electronic switch, output electrodes, and a clock generator with a solid-state output switch. The voltage converter converts low voltage from the electrical power source into a stepped-up AC voltage. The voltage multiplier for multiplying the output voltage of the converter has an additional output reservoir capacitor, the discharge of which to the output electrodes of the generator is controlled by the clock generator with a solid-state output switch. The technical result is that of providing more efficient and economical consumption of current from the electrical power source, effective immobilization of a biological target with a body mass of not less than 70-80 kg, and the possibility of stunning a target either with two output electrodes of the generator, or with one of the output electrodes and conductive wires from the electrical power source.

### FIELD OF TECHNOLOGY TO WHICH THE INVENTION RELATES

The invention relates to a technique for producing stun stepped-up voltage electric current pulses from non-lethal remote-acting electric stun weapon (RAESW), specifically small-calibre electric bullets of the RAESW that fire electric bullets, for law enforcement agencies and self-defense of citizens.

### BACKGROUND OF THE INVENTION

According to patent [1], a stun high-voltage current generator for electric bullets used for immobilizing biological objects (biological target, bio-target, target, offender) was chosen as an analogue of the claimed invention. The generator contains an electronic circuit that includes an electrical power source with an activation switch, the voltage converter that converts low voltage from the electrical power source (5-7 V) into a stepped-up AC voltage (mainly 500-1,500 V), including a microprocessor control unit controlling a power switch connected to a shell-type transformer. The output voltage of the shell-type transformer is rectified and supplied to a high-voltage stage, which includes a reservoir capacitor, a threshold device in the form of a gas discharger, an additional current capacitor and a high-voltage air-core pulse transformer. The generator was implemented only in the form of a working full-scale mock-up for a 12-calibre electric stun bullet (bullet diameter is 18.3-18.5 mm). A mock-up of a bullet with an analog generator has not been manufactured or tested. In addition, the experience of designing and prototyping an analogue generator has shown that the specified electrical circuit does not allow further miniaturization of electric bullets and does not even provide the possibility of practically feasible (serial and mechanizable process) execution of 12-calibre bullets. The analogue generator can actually only be really applicable for 8-and 4-calibre bullets (21.2-26.5 mm).

Based on the condition that it is impossible to remove an electric bullet with a stun current generator from the target offender body by the offender himself, patent [2] was chosen as an analogue of the claimed invention. The patent describes an electric bullet with two security electrodes located on the surface of its body, connected to the output electrodes of the generator (barbed needles), which are also devices for holding the electric bullet on the target's body. The disadvantage of a generator with such output and security electrodes is the design complexity (and the cost thereafter) of shaped security and non-interconnecting electrodes located on the bullet body and the low-tech nature of their reliable galvanic connection with the output electrodes of the generator, made of stainless steel due to heterogeneity of materials being connected (it is rather difficult to solder or weld copper security electrodes made of copper or aluminum foil or spraying and stainless steel).

Patent [3] was chosen as a prototype of the claimed invention. The patent (see FIG. 5) shows a circuit design for a stepped-up voltage generator for small-calibre electric bullets (namely 9 mm pistol calibre (see FIG. 1). The generator consists of an electrical power source, an activation switch, the voltage converter that converts low voltage from the electrical power source into the low AC voltage (DC/AC), a transformer that transforms low AC voltage into stepped-up AC voltage, a transformer voltage multiplier and an output electronic switch. The disadvantage of this generator is that a forward transformer voltage converter is used to convert low voltage from the electrical power source into supply voltage of the voltage multiplier, the efficiency of which, especially at low powers, as is widely known, is always obviously lower than, for example, that of flyback voltage converters. At the same time, the dimensions of forward transformer converters at low powers, as is widely known, always exceed those of flyback voltage converters.

It has been established that the main problems in designing the production and using electric bullets are the electric bullet cost (since an electric bullet is a non-durable product) and the issue of reducing dimensions (since the large dimensions of electric bullets do not make it possible to use them in short-barreled and multi-shot police and civilian non-lethal weapon (pistols and revolvers)), and, moreover, do not make it possible to avoid the risk of “commotio cordis” [4].

Another disadvantage of the generator is that the voltage multiplier used for multiplying the voltage from the converter step-up transformer cannot provide energies required to produce an effective biological effect on the target and, most importantly, the pulse durations corresponding to the bullet dimensions specified in the “Goals and advantages” section of patent [3]. For details, see the “Invention embodiment” section of this invention application. Another disadvantage of the prototype generator is that the shape of the unipolar output signal of the generator, shown in FIG. 4 of patent [3], which is a periodic square-wave signal with a duty ratio of 2 (or a mark-space ratio of 0.5), cannot be obtained from the given generator circuit in principle, since pulses arising upon discharging of voltage multiplier capacitors to a load of 250-1,000 Ohm corresponding to the load adopted by IEC, USA, RF standards for measuring parameters of electric stun weapon cannot provide a meander under the conditions of limiting the output power of the electrical power source of the generator and voltage converter with a step-up transformer and voltage multiplier at dimensions and weight suitable for placing small and medium calibre in electric bullets (see calibre classification in the “Invention embodiment” section).

Therefore, a set of the above-mentioned disadvantages of the prototype generator does not confirm the ability of the specified features to ensure technical result specified by the applicant, namely the possibility of industrial applicability in a small-calibre RAESW efficient for immobilizing a biological target. The fact that so far no small-calibre electric bullets for multi-shot hand weapon such as pistols, revolvers, rifles have been produced and sold against the background of the enormous need of law enforcement agencies in the United States and Western Europe for the RAESW that fire electric bullets confirms the inapplicability of the features specified in the prototype generator (see JNLWD (Joint Non-Lethal Weapons Directorate) “Human Electro-Muscular Incapacitation”, SBIR (Small Business Innovation Research) programs, Small calibre, non-lethal, untethered (wireless) human electro-muscular incapacitation (HEMI).

### INVENTION DISCLOSURE

The technical problem lies in the need to create a stun current generator for small-calibre electric bullets with overall dimensions and weight suitable for placing it in small-calibre electric bullets to provide more efficient and economical consumption of current from the electrical power source, effective immobilization of a biological target with a body mass of not less than 70-80 kg, the possibility of stunning a target either with two output electrodes of the generator, or with one of the output electrodes and conductive wires from the electrical power source.

The technical result consists in implementation of a stun current generator for small-calibre electric bullets for solving the specified technical problems. These technical results can be achieved by developing a stun current generator for small-calibre electric bullets consisting of an electrical power source, an activation switch, a voltage converter, a voltage multiplier, an electronic switch, output electrodes, featuring an additional clock generator with a solid-state output switch, while the voltage converter represents a step-up converter on a tapped choke that converts low voltage from the electrical power source into a stepped-up AC voltage; the voltage multiplier for multiplying the output voltage of the specified converter has an additional output reservoir capacitor, the discharge of which to the output electrodes of the generator is controlled by the clock generator with a solid-state output switch.

An additional feature is that the clock generator with a solid-state output switch also controls the operation of the specified converter.

An additional feature is that the clock generator with a solid-state output switch opens the key for the duration of the reservoir capacitor discharge, corresponding to the maximum immobilizing effect on the target.

An additional feature is that the generator circuit ground is also the additional output electrode of the generator.

### BRIEF DESCRIPTION OF DRAWINGS

FIG. 1. Structural image of the generator.

FIG. 2. External view of generator board without electrical power source, switch and board, mounted in the 11.43 mm calibre bullet head.

FIG. 3. Shape of stunning pulses generated by the generator.

### INVENTION EMBODIMENT

Since nowhere, neither foreign, nor especially domestic sources have no information on classification of the RAESW for using (throwing) of electric bullets by calibre, and, therefore, there has been no classification broken down by the calibres of the electric bullets themselves, this invention application will provide the following classification for the first time:

1. The RAESW for throwing large-calibre electric bullets is considered to be a weapon with a hunting calibre of 12 (18.3-18.5 mm) or more. Examples of large-calibre RAESW are, for example, the 12-calibre TASER X12 LLS [5] shotgun (40 mm), standard NATO Sticky Shocker [6] grenade launcher for throwing stun grenades. At the same time, the RAESW calibre greater than 12 have never been mass-produced or sold, primarily caused by the enormous probability of obtaining “commotio cordis” by the biological target, but not an electrical shock. The TASER X12 LLS electric bullet was mass-produced in the USA, but it has now been proven to be highly dangerous in terms of “commotio cordis”. It is no longer produced and has been withdrawn from circulation by the US police and the Marine Corps.

2. The RAESW for throwing medium-calibre electric bullets is considered to be a weapon with a hunting calibre below 12 and up to the calibre of small-calibre RAESW (i.e. up to 12.7 mm, see below). Electric bullets with a calibre of more than 12.7 mm are so large that short-barreled multi-shot weapon for throwing such bullets either exceed the dimensions and weight convenient for bearing, or become low-shot with 2-4 charges, which, as historical practice has shown, is no longer sufficient for police purposes and is only limitedly enough for self-defense. According to patent [7], an example of the RAESW for throwing medium-calibre electric bullets is a 14.7 mm calibre RAESW (see FIG. 13 and FIG. 14 of patent).

3. The RAESW for throwing small-calibre electric bullets is considered to be a weapon with a calibre of 12.7 mm or less. Classification of small calibre starting from 12.7 mm and less is logical because, unlike firearm bullets that have a calibre of even 2.7 mm (Kolibri) or, for example, 3.55 mm (0.14-222), electric bullets have a physical limitation to reduce the calibre due to the fact that they are microelectronic products with an output electrical power not lower than some physiologically effective one, and the obstacle for reducing the calibre is primarily the output power of power sources, the permissible transmitted and dissipated power of electronic components, as well as the physiologically minimal effective distances between stunning electrodes inserted into biological target body.

Small-calibre electric bullets for the RAESW (and, accordingly, small-calibre RAESW for throwing such electric bullets) are bullets only of those calibres that can be used in standard (known, used, in service with the police or army) samples of multi-shot short-barreled firearms such as pistols and revolvers, i.e. calibres up to 12.7 mm. An example of electric bullets for a small-calibre RAESW is the electric bullet according to patent [8]. The alleged invention describes a generator for the RAESW with a 11.43 mm calibre, i.e. small-calibre (as well as the prototype device), since many pistols and revolvers widely used, produced and applied in the world have the calibre of 11.43(. 45 ) and 9 mm.

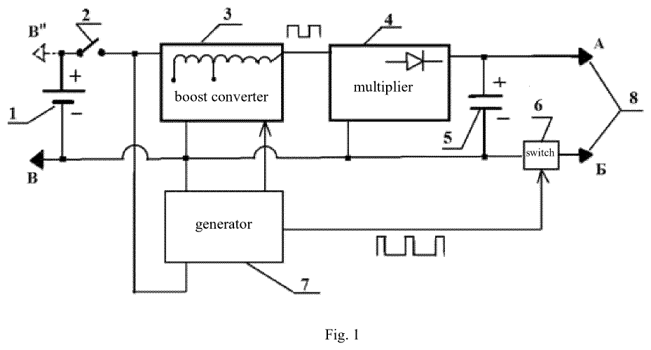

FIG. 1—The generator has power source 1 in the form of a battery or accumulator, mainly of the disk (clock) type, switch 2 that turns on when an electric bullet is fired or when it strikes the target under inertial, centrifugal, pressure or other force, step-up converter on a tapped choke 3 (boost converter, buck-boost converter, step-up converter), voltage multiplier 4, reservoir capacitor 5, solid-state output switch 6, clock generator 7 with switch 6 and output electrodes 8. Boost converter on a tapped choke 3 is used as the first stage for stepping up voltage. The use of a boost converter on a simple choke does not make it possible to step up voltage of the electrical power source to the values required for operation of a low-stage voltage multiplier with voltage multiplication to the value required for charging reservoir capacitor 5 with a current voltage effective for a physiological effect on the target, given the overall dimensions of the microcapacitors and microdiodes of the multiplier placed in small-calibre electric bullets. It is known that increasing the multiplier stages sharply reduces efficiency of the multipliers. The use of a tapped choke immediately provides the increased voltage required for operation of a low-stage multiplier with the dimensions of capacitors and diodes placed in small-calibre electric bullets.

The output voltage removed from the tapped choke amounting to about 250-300 V is supplied to voltage multiplier 4, adapted to operate with unipolar square-wave pulses, but not with sinusoidal current, as the prototype generator. The voltage received from multiplier 4, increased to 500-550 V, is supplied to reservoir capacitor 5, which is additional to the capacitors of the multiplier, which, using solid-state output switch 6, periodically discharges through output electrodes 8 to target 9 at a given switching frequency of the output switch. Output electrodes 8 of the generator are both “service electrodes” of the electric bullet and devices for securing bullet to the target. They are needles with barbs that pierce the biological target body when an electric bullet strikes it and do not allow it to come off (bounce off) from the body. During the discharge cycle of reservoir capacitor 5 to the target, boost converter 3 turns off by a signal from clock oscillator 7 with solid-state output switch 6 in order to save battery power, since the operation of boost converter 3 (and further operation of the voltage multiplier) during the discharge cycle of capacitor 5 to the target increases neither the duration nor the discharge pulse energy. In other words, it does not increase the effectiveness of physiological effect on the target, but wastes the energy of electrical power source 1. This mode of generator operation increases its operating time with constant output power (to the target) by up to 10%, which is very important due to the low energy intensity of a small-sized electrical power source.

Mounting of reservoir capacitor into the generator in order to achieve the same pulse duration as the prototype multiplier capacitor cascade has makes it possible to reduce dimensions of the generator for its placing in small-calibre electric bullets. As numerous experimental test data have shown, the voltage multiplier in the prototype generator, used to increase voltage from the converter step-up transformer, cannot provide energies required for an effective biological effect on the target (immobilization, expressed in the impossibility of active actions of the biological target (human) with a body mass of not less than 70-80 kg due to the severe tonic convulsions and completely disorienting painful sensations) and, most importantly, pulse durations in medium-and small-calibre electric bullets due to the fact that, in accordance with the law for calculating capacitance to achieve the capacitance of capacitors required to obtain the duration of pulses with the necessary physiological effect on the target, sequential inclusion of capacitors in cascade diode-capacitor multiplying circuits increases the overall volume and weight of the generator to values unacceptable for use with medium-and small-calibre electric bullets.

Depending on the actual type of capacitor and process capabilities of the manufacturer, reservoir capacitor 5 with different dimensions of the generator (i. e. different calibres of electric bullets from medium to small) will have different capacity, which, given the generator dimensions, must be as large as possible to obtain energy and duration of stunning pulse, sufficient for effective physiological effect on the target for its immobilization. Therefore, the clock generator with a solid-state output switch has a chain for regulating duty ratio of the switch pulses (the time of its closed and open states), selected upon achieving the greatest effectiveness of physiological effect on the target.

When the electric bullet with a generator strikes the offender body, the pulsed electric current stunning the target comes from output electrodes 8 and passes through the body between A and B poles, causing immobilization of the offender. When the electric bullet strikes parts of the offender's body that are insensitive to electric current (for example, in areas with large deposits of fatty tissue), some offenders, especially those under the influence of alcohol and drugs, may, overcoming pain by force of will, try to instinctively pull the electric bullet which is a source of pain out of their body. To prevent this, the analogue specified in patent [2] provides complex-shaped security electrodes connected to the output electrodes. Prototype patent [3] provides no security electrodes. The claimed generator provides a “third” additional output electrode B and/or B”, which is actually the ground and at the same time a security electrode. When the electric bullet strikes the offender body, the stunning pulses pass through the body between A and B poles of output electrodes 8, but when the offender tries to touch the “third” electrode B and/or B”, the electrical stunning pulses begin to pass between electrode A and the “third” electrode B and/or B”. Moreover, although the resistance of the offender's body, for example, between the fingers trying to pull the electric bullet out of the body and the place where it strikes, for example, the leg, is much greater than that of the body between A and B poles of electrodes 8, located only 10 mm apart from each other in the electric bullet (for example, 11.43 mm calibre bullet), current loop [9] between pole A and the “third” electrode B and/or B” is rather large, which means the stunning effect of a weak current limited to high resistance is extremely high and, as experimental data have shown, is not inferior to the physiological effect between output service electrodes 8. Experimental data have shown that a person is not able to independently remove an electric bullet that has entered the body with his bare hand. The “third” electrode of the generator is simply brought out onto the outer surface of the bullet, for example, covered with metal foil or metallized, but not in contact with output electrodes 8.

### Implementation Example

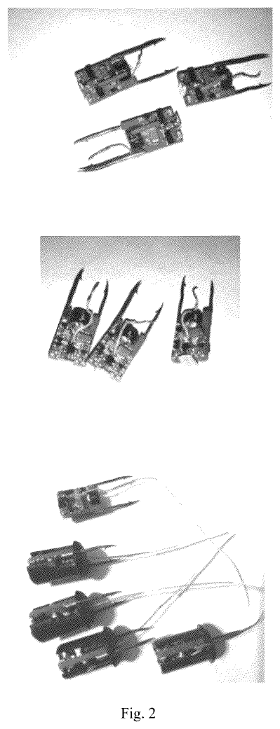

FIG. 2 shows generator boards ready for placement in 11.43 mm calibre electric bullet housings, and boards mounted in the head of the 11.43 mm calibre bullet. The total weight of the generator board with output electrodes is 0.95 g. The generator has an output electrical power of 0.25 W, with pulses of about 4.0-4.5 ms at a load of 1,000 Ohm, with the under a load amplitude of about 550 V and energy per pulse about 0.008 J at a frequency of 35 Hz. Such characteristics are sufficient for reliable immobilization of a biological target with a body mass of not less than 70-80 kg, when introducing the output electrodes of an electric bullet generator into the human subcutaneous tissue and pectoral muscles, abdomen and limbs.

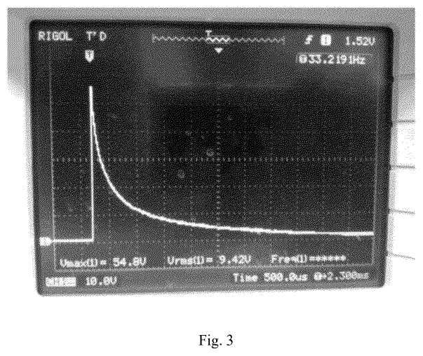

FIG. 3 shows the shape of the unit pulse generated by the generator. When the generator operates at a load of 250-1,000 Ohm, corresponding to the load simulating the biological target body accepted by the standards, the generator produces exponential pulses, not rectangular ones (as indicated for the prototype generator).

### LIST OF CITED SOURCES

1. Patent of the Russian Federation No. 2583970
2. Patent of the Russian Federation No. 2788236
3. Patent of the U.S. Pat. No. 5,698,815
4. Yu. O. Ladyagin “Remote-acting electric stun weapon”, Moscow: Stalingrad Foundation Publishing House, 2017, p. 251.
5. Yu. O. Ladyagin “Remote-acting electric stun weapon”, Moscow: Stalingrad Foundation Publishing House, 2017, pp. 254-255.
6. Yu. O. Ladyagin “Remote-acting electric stun weapon”, Moscow: Stalingrad Foundation Publishing House, 2017, p. 250.
7. Patent of the Russian Federation No. 2788236
8. Patent of the Russian Federation No. 2758476
9. Yu. O. Ladyagin “Remote-acting electric stun weapon”, Moscow: Stalingrad Foundation Publishing House, 2017, pp. 354-355.

1. A stun current generator for small-calibre electric bullets consisting of an electrical power source, an activation switch, a voltage converter, a voltage multiplier, an electronic switch, output electrodes, features an additional clock generator with a solid-state output switch, while the voltage converter represents a step-up converter on a tapped choke that converts low voltage from the electrical power source into a stepped-up AC voltage; the voltage multiplier for multiplying the output voltage of the specified converter has an additional output reservoir capacitor, the discharge of which to the output electrodes of the generator is controlled by the clock generator with a solid-state output switch.

2. According to cl. 1, the generator features an additional clock generator with a solid-state output switch that also controls the operation of the specified converter.

3. According to cl. 1, the generator features an additional clock generator with a solid-state output switch that opens the key for the duration of the reservoir capacitor discharge, corresponding to the maximum immobilizing effect on the target.

4. According to cl. 1, the generator features the additional output electrode that is also the generator circuit ground.
